(19) United States
(12) Patent Application Publication
(10) Pub. No.: US 2012/0160556 A1
(43) Pub. Date: Jun. 28, 2012

(54) Circuit board and method of manufacturing the same

(75) Inventors: Joonsung Kim, Gyeonggi-do (KR); Goingsik Kim, Busan (KR); Changsup Ryu, Gyeongg-do (KR)

(73) Assignee: SAMSUNG ELECTRO-MECHANICS CO., LTD., Suwon (KR)

(21) Appl. No.: 13/373,299

(22) Filed: Nov. 10, 2011

(30) Foreign Application Priority Data
Dec. 27, 2010 (KR) 10-2010-0135629

(51) Int. Cl. H05K 1/11; H05K 3/10

(52) U.S. Cl. 174/266; 29/846

(57) ABSTRACT

Provided is a circuit board including a base substrate on which an internal circuit structure is formed, an insulating material configured to cover the base substrate and having a via-hole configured to expose the internal circuit pattern, an external circuit structure formed on the insulating material and electrically connected to the internal circuit structure through the via-hole, and a solder resist pattern configured to cover the insulating material to expose the external circuit structure, wherein the insulating material has a structure in which an adhesion surface between the insulating material and the solder resist pattern is stepped with respect to an adhesion surface between the insulating material and the external circuit structure.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2010-0135629, entitled filed Dec. 27, 2010, which is hereby incorporated by reference in its entirety into this application.

### BACKGROUND OF THE INVENTION

1. Field of the Invention

The present invention relates to a circuit board and a method of manufacturing the same, and more particularly, to a printed circuit board (PCB) capable of increasing adhesion between a substrate-stack body and a solder resist pattern, and a method of manufacturing the same.

2. Description of the Related Art

A process of manufacturing a build-up printed circuit board widely used for packaging of a semiconductor integrated circuit chip includes a process of manufacturing a substrate-stack body by stacking and plasticizing a plurality of insulating films. In recent times, since a line width of a circuit pattern of a semiconductor integrated circuit chip is extremely micro-sized, a fine pitch of the line width of the build-up printed circuit board is also needed for packaging of the semiconductor integrated circuit chip.

As a typical circuit board manufacturing process capable of accomplishing a fine pitch of a circuit line width, a semi-addictive process (SAP) is provided. In a conventional SAP, an insulating material such as a prepreg layer is formed on a base substrate to form a substrate-stack body, a metal catalyst such as palladium (Pd) is coated on the substrate-stack body, and then, chemical copper is formed on the insulating material using the metal catalyst. Then, a resist film is formed on the base substrate, on which the chemical copper is formed. After an exposure and development process, a predetermined chemical and electro-plating process is performed to form a circuit pattern on the substrate-stack body. Next, a solder resist pattern is formed on the substrate-stack body to selectively expose the circuit pattern, manufacturing the circuit board.

However, in the case of the SAP, the metal catalyst such as Pd may not be completely removed during the process of manufacturing the circuit board. In this case, due to the remaining metal catalyst, a metal-plated film formed on the insulating material may be spread or diffused to the other region, rather than a preset region, to decrease manufacturing efficiency of the circuit board. In addition, in order to form a miniaturized circuit pattern, an outer layer insulating material having a small profile is used. In this case, since adhesion between the insulating material and the solder resist pattern is weakened, the solder resist pattern may come off from the insulating material.

### SUMMARY OF THE INVENTION

The present invention has been invented in order to overcome the above-described problems and it is, therefore, an object of the present invention to provide a circuit board having a structure capable of improving adhesion between an insulating material and a solder resist pattern.

It is another object of the present invention to provide a method of manufacturing a circuit board capable of improving adhesion between an insulating material and a solder resist pattern.

It is still another object of the present invention to provide a method of manufacturing a circuit board capable of preventing a plating film from spreading due to a remaining metal catalyst film during a process of manufacturing the circuit board.

In accordance with one aspect of the present invention to achieve the object, there is provided a circuit board including: a base substrate on which an internal circuit structure is formed; an insulating material configured to cover the base substrate and having a via-hole configured to expose the internal circuit pattern; an external circuit structure formed on the insulating material and electrically connected to the internal circuit structure through the via-hole; and a solder resist pattern configured to cover the insulating material to expose the external circuit structure, wherein the insulating material has a structure in which an adhesion surface between the insulating material and the solder resist pattern is stepped with respect to an adhesion surface between the insulating material and the external circuit structure.

According to an embodiment of the present invention, the adhesion surface between the insulating material and the solder resist pattern may be disposed inside the insulating material in comparison with the adhesion surface between the insulating material and the external circuit board.

According to an embodiment of the present invention, a first region to which the insulating material and the external circuit structure are adhered and a second region to which the insulating material and the solder resist pattern are adhered may form a concave and convex structure, wherein the first region forms a convex part of the concave and convex structure which projects to the outside, and the second region forms a concave part of the concave and convex structure which is recessed toward the base substrate.

According to an embodiment of the present invention, the insulating material may include a prepreg layer, and the external circuit structure may include a conductive via connected to the internal circuit structure through the prepreg layer, and an external circuit pattern formed on the prepreg layer to be electrically connected to the conductive via.

According to an embodiment of the present invention, the circuit board may further include a plating film formed on the external circuit structure selectively exposed by the solder resist pattern, wherein the plating film is used as a bonding pad to which a bonding wire is adhered.

In accordance with another aspect of the present invention to achieve the object, there is provided a method of manufacturing a circuit board including: preparing a base substrate; forming an internal circuit structure on the base substrate; forming an insulating material having a via-hole configured to expose the internal circuit structure on the base substrate; forming an external circuit structure electrically connected to the internal circuit structure through the via-hole on the insulating material; forming a step structure on the insulating material; and forming a solder resist pattern configured to expose the external circuit structure on the insulating material.

According to an embodiment of the present invention, forming the step structure may include performing a plasma etching process to the insulating material.

According to an embodiment of the present invention, forming the step structure may include removing a region of the insulation material selectively exposed by the external circuit pattern such that a second region to which the insulating material and the solder resist pattern are adhered is disposed inside the insulating material in comparison with a first region to which the insulating material and the external circuit pattern are adhered.

According to an embodiment of the present invention, forming the step structure may be performed before forming the solder resisting pattern to etch the insulating material region exposed by the external circuit structure.

According to an embodiment of the present invention, forming the step structure may be performed after forming the solder resist pattern to etch the region of the insulating material exposed by the solder resist pattern.

According to an embodiment of the present invention, forming the insulating material may include laminating a prepreg layer on the base substrate, and forming the external circuit pattern may include: coating a metal catalyst on the prepreg layer; forming chemical copper on the prepreg layer; and performing a plating process using the chemical copper as a seed layer.

According to an embodiment of the present invention, performing the etching process may include removing the chemical copper except the external circuit pattern before forming the solder resist pattern.

According to an embodiment of the present invention, the method may further include forming a plating film on the external circuit structure selectively exposed by the solder resist pattern, wherein the plating film is used as a bonding pad to which a bonding wire is adhered.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a circuit board in accordance with an exemplary embodiment of the present invention;

FIG. 2 is a flowchart showing a method of manufacturing a circuit board in accordance with an exemplary embodiment of the present invention; and

FIGS. 3A to 3G are cross-sectional views for explaining a process of manufacturing a circuit board in accordance with an exemplary embodiment of the present invention.

### DETAILED DESCRIPTION OF THE PREFERABLE EMBODIMENTS

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. To clearly describe the present invention, parts not relating to the description are omitted from the drawings. Like numerals refer to like elements throughout the description of the drawings.

The terms used throughout this specification are provided to describe embodiments but not intended to limit the present invention. In this specification, a singular form includes a plural form unless the context specifically mentions. When an element is referred to as “comprises” and/or “comprising”, it does not preclude another component, step, operation and/or device, but may further include the other component, step, operation and/or device unless the context clearly indicates otherwise.

Hereinafter, a circuit board and a method of manufacturing the same in accordance with an exemplary embodiment of the present invention will be described in detail with reference to the accompanying drawings.

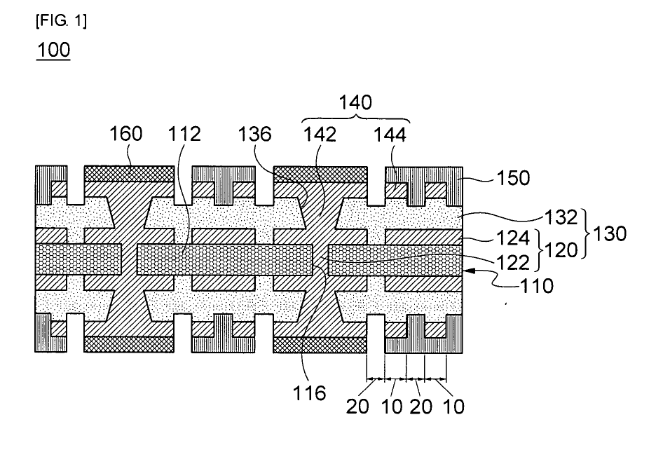

FIG. 1 is a view showing a circuit board in accordance with an exemplary embodiment of the present invention. Referring to FIG. 1, a circuit board 100 in accordance with an exemplary embodiment of the present invention may include a substrate-stack body 130, an external circuit pattern 140 formed on the substrate-stack body 130, a solder resist pattern 150, and a plating film 160. In addition, the substrate-stack body 130 may include a base substrate 110, an internal circuit structure 120, and an insulating material 132.

The base substrate 110 may include a core layer 112 and a metal layer (not shown) formed on both surfaces of the core layer 112. The core layer 112 may be various kinds of insulating films. For example, the core layer 112 may be an insulating film formed of any one material selected from polyimide, polyimide amide, polyester, polyphenylene sulfide, and polyesterimide. The metal layer may be metal layer including copper (Cu). The base substrate 110 may use a copper clad laminate (CCL).

The internal circuit structure 120 may include a first via 122 and an internal circuit pattern 123 electrically connected to the first via 122. The first via 122 may be a conductive via passing through the base substrate 110. For this, a through-hole 116 is formed in the base substrate 110 to pass through the core layer 112. The first via 122 may be formed to fill the through-hole 116. The internal circuit pattern 124 may be formed on the base substrate 110 to be partially electrically connected to the first via 122.

The insulating material 132 may cover the base substrate 110 to selectively expose the internal circuit structure 120. The insulating material 132 may include a prepreg layer configured to cover the base substrate 110.

The external circuit structure 140 may include a second via 142 and an external circuit pattern 144 electrically connected to the second via 142. The second via 142 may be a conductive via passing through the insulating material 132 to be electrically connected to the internal circuit pattern 124. For this, the insulating material 132 has a via-hole 136 passing through the insulating material 132 to expose the internal circuit pattern 124. The second via 142 may be formed to fill the via-hole 136. The external circuit pattern 144 may be formed on the insulating material 132 to be partially electrically connected to the second via 142.

The solder resist pattern 150 may be formed on the insulating material 132 to selectively expose the external circuit structure 140. Here, the solder resist pattern 150 may cover the substrate-stack body 130 to increase adhesion to the insulating material 132. More specifically, the substrate-stack body 130 may include a region 10 (hereinafter, referred to as a first region) to which the external circuit pattern 144 and the insulating material 132 are adhered, and a region 10 (hereinafter, referred to as a second region) to which the solder resist pattern 150 and the insulating material 132 are adhered. Here, the first region 10 and the second region 20 may be disposed at different heights to form a step structure.

The step structure may be provided to increase an adhesion area between the solder resist pattern 150 and the substrate-stack body 130. For example, the second region 20 may be provided to be disposed at an inside of the insulating material 132 in comparison with the first region 10. Accordingly, the first region 10 and the second region 20 have a concave and convex structure. The first region 10 forms a convex part of the concave and convex structure, which projects toward the outside, and the second region 20 forms a concave part of the concave and convex structure, which is recessed toward the base substrate 110. While the first region 10 and the second region 20 have the concave and convex structure, in this case, the second region 20 may be further recessed toward the base substrate 110 than the first region 10. Due to the concave and convex structure, since the solder resist pattern 150 is further inserted into the insulating material 132 than the external circuit pattern 132 to be adhered to the insulating material 132, the adhesion area between the solder resist pattern 150 and the insulating material 132 can be increased and thus adhesion between the solder resist pattern 150 and the substrate-stack body 130 can also be increased.

As described above, the circuit board in accordance with an exemplary embodiment of the present invention includes the substrate-stack body 130 having the insulating material 132 with a step surface structure, and the solder resist pattern 150 configured to cover the insulating material 132. Here, the solder resist pattern 150 may have a structure in which an adhesion area to the insulating material is increased by the step structure. Accordingly, the circuit board in accordance with the present invention increases the adhesion area between the substrate-stack body and the solder resist pattern and the adhesion between the solder resist pattern and the insulating material of the substrate-stack body to prevent the solder resist pattern from coming off. In addition, due to the adhesion structure between the solder resist pattern 150 and the substrate-stack body 130, a thickness of the solder resist pattern 150 can be reduced.

Continuously, the method of manufacturing the circuit board in accordance with an exemplary embodiment of the present invention will be described. Hereinafter, detailed description of the circuit board 100 in accordance with an exemplary embodiment of the present invention as described above will be omitted or simplified.

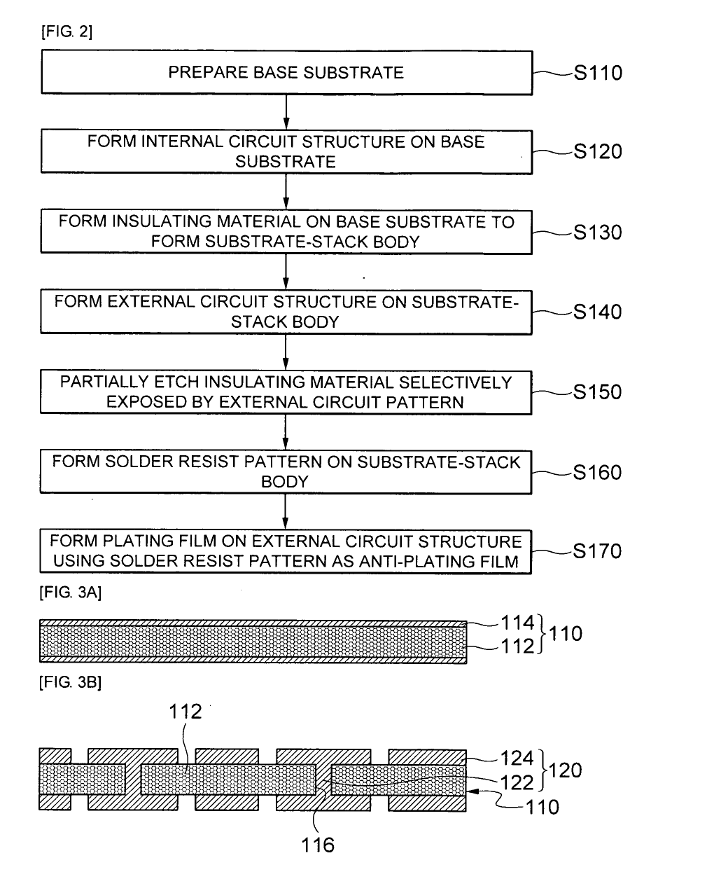

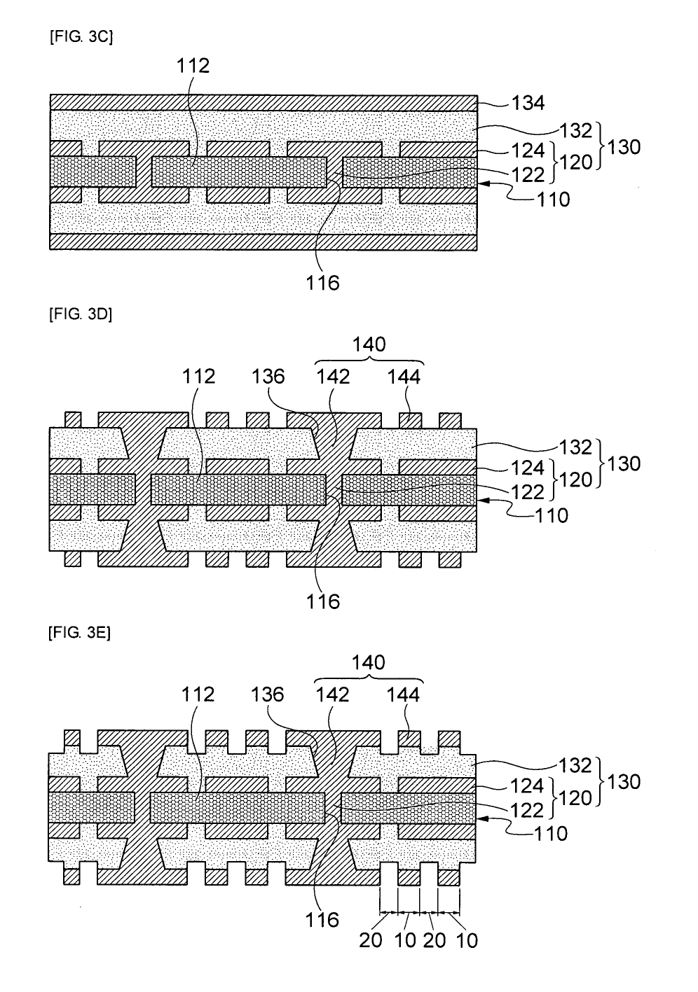

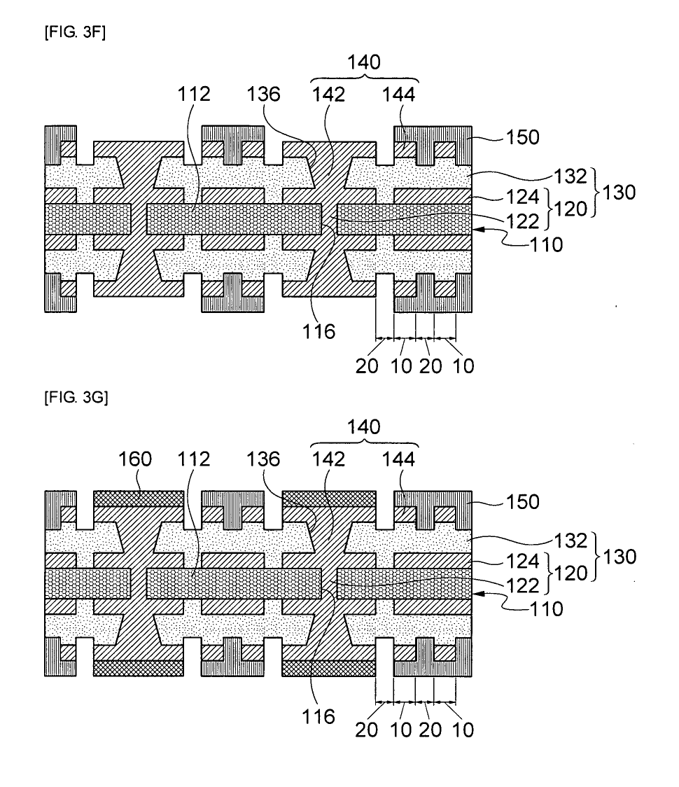

FIG. 2 is a flowchart showing a method of manufacturing a circuit board in accordance with an exemplary embodiment of the present invention, and FIGS. 3A to 3G are cross-sectional views for explaining a process of manufacturing a circuit board in accordance with an exemplary embodiment of the present invention.

Referring to FIGS. 2 and 3A, a base substrate 110 may be prepared (S110). Preparing the base substrate 110 may include preparing a thin plate formed of a core layer 112 and a metal layer 114 covering both surfaces of the core layer 112. For example, preparing the base substrate 110 may include preparing a CCL.

Referring to FIGS. 2 and 3B, an internal circuit structure 120 may be formed on the base substrate 110 (S120). For example, a via-hole 116 may be formed on the base substrate 110. The via-hole 116 may be a through-hole passing through the base substrate 110. In addition, chemical copper (not shown) may be formed on the base substrate 110.

A plating film may be formed on the base substrate 110 by performing a plating process. For example, a first resist pattern (not shown) may be formed on the base substrate 110. Forming the first resist pattern may include laminating a dry film resist (DFR) on the base substrate 110. A copper plating process may be performed with respect to the resultant matter, on which the first resist pattern is formed, using the chemical copper as a seed layer. Accordingly, a copper plating film may be formed on the base substrate 110 in a region, which is selected exposed by the first resist pattern. Then, the first resist pattern and the chemical copper plating film may be selectively removed. Therefore, the inner circuit structure 120 constituted by a first via 122 passing through the base substrate 110 and an inner circuit pattern 124 electrically connected to the first via 122 may be formed on the base substrate 110.

Referring to FIGS. 2 and 3C, an insulating material 132 may be formed on the base substrate 110 to form a substrate-stack body 130 (S130). For example, the insulating material 132 may be formed on the base substrate 110 to seal the internal circuit structure 120. Forming the insulating material 132 may include forming a prepreg layer on the base substrate 110. Forming the prepreg layer may be performed by laminating a polymer sheet having a resin-based material on both surfaces of the base substrate 110. Then, stacking a copper film on the insulating material 132 may be further performed. Here, before stacking the copper film on the insulating material 132, forming an adhesive insulating material (not shown) on the prepreg layer may be further added. The adhesive insulating material may be provided to form a conductive film on the prepreg layer. For example, the adhesive insulating material may be formed of an insulating material having adhesive property such as PCF.

Referring to FIGS. 2 and 3D, an external circuit structure 140 may be formed on the substrate-stack body 130 (S140). For example, a second via-hole 136 may be formed in the substrate-stack body 130. Forming the second via-hole 136 may include forming a hole in the insulating material 132 of the substrate-stack body 130 to expose the internal circuit pattern 124 of the internal circuit structure 120. Forming the second via-hole 136 may be performed through laser cutting, drilling, and other various punching processes. Here, a copper foil 134 (see FIG. 3C) can prevent damage to the insulating material 132 during the process of forming the second via-hole 136. When the second via-hole 136 is completely formed, the copper foil 134 may be removed.

A catalyst material (not shown) may be coated on the substrate-stack body 130. For example, the catalyst material may be a Pd catalyst. The chemical copper may be formed on the substrate-stack body 130 using the catalyst material. Then, a plating process may be performed on the substrate-stack body 130 to form a plating film. For example, a second resist pattern (not shown) may be formed on the substrate-stack body 130, and a copper plating process using the chemical copper as a seed layer may be performed. Accordingly, a copper plating film may be formed on a region of the insulating material 142 selectively exposed by the second resist pattern on the substrate-stack body 130. Then, the second resist pattern and the chemical copper may be selectively removed.

Through the above processes, the external circuit structure 140 constituted by a second via 142 connected to the internal circuit pattern 124 through the insulating material 132 and an external circuit pattern 144 electrically connected to the second via 142 on the substrate-stack 130 may be formed on the base substrate 110. Here, the second via 142 may be configured as a structure stacked on the first via 122.

Referring to FIGS. 2 and 3E, the insulating material 132 selectively exposed by the external circuit structure 140 may be etched (S150). For example, a dry etching process may be performed with respect to the substrate-stack body 130. The dry etching process may use a process having high selectivity with respect to a region of the insulating material 132. For example, the dry etching process may use a plasma etching process. The plasma etching process may selectively etch the region of the insulating material 132 selectively exposed by the external circuit pattern 144. For this, after preparing a plasma etching apparatus (not shown), the substrate-stack body 130 may be loaded into the plasma etching apparatus (not shown) to perform a plasma treatment process.

By the dry etching process, residues such as the catalyst material, etc. remaining on the surface of the insulating material 132 may be removed. More specifically, the catalyst material such as Pd used to form the external circuit structure 140 may be remained on the substrate-stack body 130. Among the remaining catalyst material, the catalyst material remaining around the region in which a bonding pad is formed may act to cause the plating film to be spread or diffused to a preset region. In order to prevent the spreading or diffusion, the dry etching process may be performed to remove the catalyst material remaining on the surface of the insulating material.

In particular, it is difficult to completely remove the remaining material through a general surface treatment. Accordingly, the dry etching process using plasma etches the second region 20 such that the second region 20 is recessed into the insulating material in comparison with the first region 10. In this case, the catalyst material on the second region 20 selectively exposed by the external circuit pattern 144 on the substrate-stack body 130 may be completely removed. In addition, by the dry etching process, a step may be formed between the first region 10 and the second region 20, and the step may have a structure in which the second region 20 is disposed adjacent to the base substrate 110 in comparison with the first region 10.

Referring to FIGS. 2 and 3F, a solder resist pattern 150 may be formed on the substrate-stack body 130 (S160). For example, forming the solder resist pattern 150 may include forming a resist film on the substrate-stack body 130 and selectively removing a portion of the resist film to partially expose a region of the external circuit pattern 144. Accordingly, the solder resist pattern 150 configured to selectively expose the external circuit pattern 144 may be formed on the substrate-stack body 130.

Meanwhile, since the solder resist pattern 150 is formed on the resultant matter having the step structure in which the first region 10 has a larger depth than the second region 20, an adhesion surface between the solder resist pattern 150 and the insulating material 132 may have a structure extending into the insulating material 132 in comparison with an adhesion surface between the external circuit pattern 144 and the insulating material 132. In this case, since the adhesion area between the solder resist pattern 150 and the substrate-stack body 130 is increased, a structure in which adhesion to the insulating material 132 is increased can be provided.

Referring to FIGS. 2 and 3G, a plating film 160 may be formed on the external circuit structure 140 using the solder resist pattern 150 as an anti-plating film (S170). For example, forming the plating film 160 may include forming a predetermined plating film 160 on the external circuit pattern 144 of the external circuit structure 140 selectively exposed by the solder resist pattern 150. For example, forming the plating film 160 may include forming a gold plating film. In this case, a portion of the external circuit pattern 144 on which the gold plating film is formed may be used as a bonding pad, to which the bonding wire (not shown) is connected, to electrically connect the circuit board and the semiconductor integrated circuit (not shown).

Meanwhile, during the plating process, it is possible to prevent the plating film 160 from spreading to the other region, rather than a preset region. More specifically, before performing the plating process, the metal catalyst, which is previously used, may remain on the substrate-stack body 130. In particular, since the metal catalyst such as Pd cannot be easily removed through a general cleaning process, the metal catalyst may easily remain on the substrate-stack body 130. When the metal plating process is performed on the substrate-stack body 130 with the metal catalyst remained, the metal catalyst may be spread or diffused to the other region, rather than the preset region, by the metal catalyst to decrease manufacturing efficiency of the substrate. However, in the present invention, as the substrate-stack body 130 selectively exposed by the external circuit pattern 144 is etched through a plasma etching process, the metal catalyst remaining on the substrate-stack body 130 can be effectively removed. In particular, process conditions of the plasma etching process may be set such that a region exposed by the external circuit pattern 144 (i.e., the second region 20) is etched to be relatively further stepped with respect to a region at which the external circuit pattern 144 is covered (i.e., the first region 10). Accordingly, since the metal catalyst remaining in the region of the insulating material 132 of the substrate-stack body 130 exposed by the external circuit pattern 144 can be completely removed, it is possible to prevent the plating film from spreading due to the metal catalyst during the plating process.

While the embodiment exemplarily described that the insulating material 132 selectively exposed by the external circuit structure 140 is etched and then the solder resist patter 150 is formed, forming the step structure on the insulating material 132 may be variously applied to the process of manufacturing the circuit board. For example, forming the step structure on the insulating material 132 may be performed after forming the solder resist pattern 150. More specifically, performing the dry etching process with respect to the insulating material 132 may be performed to selectively etch the region of the insulating material 132 exposed by the solder resist pattern 150 after the solder resist pattern 150 is formed. In this case, the step structure formed in the insulating material may be provided between the solder resist pattern 150 and the external circuit pattern 144 selectively exposed by the solder resist pattern 150.

As described above, according to the method of manufacturing the circuit board in accordance with an exemplary embodiment of the present invention, it is possible to manufacture the circuit board 100 in which the adhesion surface between the substrate-stack body 130 and the solder resist pattern 150 and the adhesion surface between the substrate-stack body 130 and the external circuit pattern 144 form the concave and convex structure, increasing the adhesion area between the substrate-stack body 130 and the solder resist pattern 150. Accordingly, according to the method of manufacturing the circuit board in accordance with the present invention, it is possible to manufacture the circuit board having a structure in which the adhesion area between the substrate-stack body and the solder resist pattern is increased to improve the adhesion between the substrate-stack body and the solder resist pattern.

In addition, according to the method of manufacturing the circuit boar in accordance with an exemplary embodiment of the present invention, the dry etching process is performed on the region of the substrate-stack body 130 selectively exposed by the external circuit pattern 144 to effectively remove the metal catalyst remaining on the substrate-stack body 130, preventing the plating film from spreading to the other region, rather than the preset region, due to the remaining metal catalyst during the plating process.

As can be seen from the foregoing, according to the circuit board in accordance with the present invention, since the adhesion area between the substrate-stack body and the solder resist pattern is increase, it is possible to provide the structure in which the adhesion between the substrate-stack body and the solder resist pattern is improved.

According to the method of manufacturing the circuit board in accordance with the present invention, since the adhesion between the substrate-stack body and the solder resist pattern is increased, it is possible to manufacture the circuit board having a structure in which the adhesion between substrate-stack body and the solder resist pattern is improved.

According to the method of manufacturing the circuit board in accordance with the present invention, since the dry etching process is formed on the region of the substrate-stack body selectively exposed by the external circuit pattern to effectively remove the metal catalyst remaining on the substrate-stack body, it is possible to prevent the plating film from spreading to the other region, rather than the preset region, due to the remaining metal catalyst during the plating process.

This invention may be embodied in different forms and should not be construed as limited to the embodiments set forth herein. Rather, these embodiments are provided so that this disclosure will be thorough and complete, and will fully convey the scope of the invention to those skilled in the art. As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A circuit board comprising:
a base substrate on which an internal circuit structure is formed;
an insulating material configured to cover the base substrate and having a via-hole configured to expose the internal circuit pattern;
an external circuit structure formed on the insulating material and electrically connected to the internal circuit structure through the via-hole; and
a solder resist pattern configured to cover the insulating material to expose the external circuit structure,
wherein the insulating material has a structure in which an adhesion surface between the insulating material and the solder resist pattern is stepped with respect to an adhesion surface between the insulating material and the external circuit structure.

2. The circuit board according to claim 1, wherein the adhesion surface between the insulating material and the solder resist pattern is disposed inside the insulating material in comparison with the adhesion surface between the insulating material and the external circuit board.

3. The circuit board according to claim 1, wherein a first region to which the insulating material and the external circuit structure are adhered and a second region to which the insulating material and the solder resist pattern are adhered form a concave and convex structure, wherein the first region forms a convex part of the concave and convex structure which projects to the outside, and the second region forms a concave part of the concave and convex structure which is recessed toward the base substrate.

4. The circuit board according to claim 1, wherein the insulating material comprises a prepreg layer, and
the external circuit structure comprises a conductive via connected to the internal circuit structure through the prepreg layer, and
an external circuit pattern formed on the prepreg layer to be electrically connected to the conductive via.

5. The circuit board according to claim 1, further comprising a plating film formed on the external circuit structure selectively exposed by the solder resist pattern,
wherein the plating film is used as a bonding pad to which a bonding wire is adhered.

6. A method of manufacturing a circuit board comprising:
preparing a base substrate;
forming an internal circuit structure on the base substrate;
forming an insulating material having a via-hole configured to expose the internal circuit structure on the base substrate;
forming an external circuit structure electrically connected to the internal circuit structure through the via-hole on the insulating material;
forming a step structure on the insulating material; and
forming a solder resist pattern configured to expose the external circuit structure on the insulating material.

7. The method according to claim 6, wherein forming the step structure comprises performing a plasma etching process to the insulating material.

8. The method according to claim 6, wherein forming the step structure comprises removing a region of the insulation material selectively exposed by the external circuit pattern such that a second region to which the insulating material and the solder resist pattern are adhered is disposed inside the insulating material in comparison with a first region to which the insulating material and the external circuit pattern are adhered.

9. The method according to claim 6, wherein forming the step structure is performed before forming the solder resisting pattern to etch the insulating material region exposed by the external circuit structure.

10. The method according to claim 6, wherein forming the step structure is performed after forming the solder resist pattern to etch the region of the insulating material exposed by the solder resist pattern.

11. The method according to claim 6, wherein forming the insulating material comprises laminating a prepreg layer on the base substrate, and
forming the external circuit pattern comprises:
coating a metal catalyst on the prepreg layer;
forming chemical copper on the prepreg layer; and
performing a plating process using the chemical copper as a seed layer.

12. The method according to claim 11, wherein performing the etching process comprises removing the chemical copper except the external circuit pattern before forming the solder resist pattern.

13. The method according to claim 6, further comprising forming a plating film on the external circuit structure selectively exposed by the solder resist pattern,
wherein the plating film is used as a bonding pad to which a bonding wire is adhered.

14. The circuit board according to claim 2, further comprising a plating film formed on the external circuit structure selectively exposed by the solder resist pattern,
wherein the plating film is used as a bonding pad to which a bonding wire is adhered.

15. The circuit board according to claim 3, further comprising a plating film formed on the external circuit structure selectively exposed by the solder resist pattern,
wherein the plating film is used as a bonding pad to which a bonding wire is adhered.

16. The circuit board according to claim 4, further comprising a plating film formed on the external circuit structure selectively exposed by the solder resist pattern,
wherein the plating film is used as a bonding pad to which a bonding wire is adhered.

17. The method according to claim 7, further comprising forming a plating film on the external circuit structure selectively exposed by the solder resist pattern,
wherein the plating film is used as a bonding pad to which a bonding wire is adhered.

18. The method according to claim 8, further comprising forming a plating film on the external circuit structure selectively exposed by the solder resist pattern,
wherein the plating film is used as a bonding pad to which a bonding wire is adhered.

19. The method according to claim 9, further comprising forming a plating film on the external circuit structure selectively exposed by the solder resist pattern,
wherein the plating film is used as a bonding pad to which a bonding wire is adhered.

20. The method according to claim 10, further comprising forming a plating film on the external circuit structure selectively exposed by the solder resist pattern,
wherein the plating film is used as a bonding pad to which a bonding wire is adhered.

21. The method according to claim 11, further comprising forming a plating film on the external circuit structure selectively exposed by the solder resist pattern,
wherein the plating film is used as a bonding pad to which a bonding wire is adhered.

22. The method according to claim 12, further comprising forming a plating film on the external circuit structure selectively exposed by the solder resist pattern,
wherein the plating film is used as a bonding pad to which a bonding wire is adhered.
